(19) United States
(12) Patent Application Publication
(10) Pub. No.: US 2013/0256293 A1
(43) Pub. Date: Oct. 3, 2013

(54) HEAT TREATMENT SYSTEM, HEAT TREATMENT METHOD, AND NON-TRANSITORY COMPUTER-READABLE RECORDING MEDIUM

(71) Applicant: TOKYO ELECTRON LIMITED, Tokyo (JP)

(72) Inventors: Yuichi TAKENAGA, Oshu-shi (JP); Wenling WANG, Oshu-shi (JP)

(73) Assignee: Tokyo Electron Limited, Tokyo (JP)

(21) Appl. No.: 13/852,396

(22) Filed: Mar. 28, 2013

(30) Foreign Application Priority Data
Mar. 29, 2012 (JP) 2012-077868

(51) Int. Cl. H01L 21/67

(52) U.S. Cl. CPC H01L 21/67098
USPC 219/413

(57) ABSTRACT

In accordance with some embodiments of the present disclosure, a heat treatment system, a heat treatment method, and a program are provided. The heat treatment system includes a heating unit configured to heat an inside of a processing chamber receiving a plurality of objects to be processed, a heat treatment condition storing unit configured to store a heat treatment condition, a power change model storing unit configured to store a model showing a relationship between a temperature change inside the processing chamber and a power change of the heating unit, a changed temperature receiving unit configured to receive information on a change of the temperature inside the processing chamber, a power calculation unit configured to calculate power of the heating unit required at a changed temperature, and a determining unit configured to determine whether the power of the heating unit calculated by the power calculation unit is saturated.

### CROSS-REFERENCE TO RELATED APPLICATION

This application claims the benefit of Japanese Patent Application No. 2012-077868, filed on Mar. 29, 2012, in the Japan Patent Office, the disclosure of which is incorporated herein in its entirety by reference.

1. Technical Field

The present disclosure relates to a heat treatment system, a heat treatment method, and a program which thermally process an object to be processed such as a semiconductor wafer or the like, particularly, a batch type heat treatment system, heat treatment method, and program which batch-process a plurality of objects to be processed.

2. Background

In a process of manufacturing a semiconductor device, there a batch type heat treatment system has been used that batch-performs a film forming process, an oxidation process, or a diffusion process on a plurality of objects to be processed such as semiconductor wafers. In the batch type heat treatment system, it is possible to efficiently process a semiconductor wafer, but it is difficult to uniformly perform a heat-treatment on a plurality of semiconductor wafers.

To solve such a problem, a heat treatment apparatus that automatically regulates an outdoor temperature has been proposed, such that the outdoor temperature introduced into a heater can become constant.

However, the power of a heater used to regulate a temperature is influenced by the power of other heaters disposed in an adjacent zone, and thus can be increased or decreased. Also, a recent energy saving heater has much lower power output than a conventional heater, and thus, even when the temperature is slightly regulated, power of the recent energy saving heater can be saturated (0% or 100%). If power of a heater is saturated, it is unable to accurately control the temperature, and further the reproducibility of heat treatment can be reduced. For this reason, it is required to regulate the temperature of a heater in consideration of the power of the heater.

As described above, because it is difficult to regulate the temperature of the heater, an operator of a heat treatment system should finely regulate the temperature on on the basis of an experience or a sense. Thus, there is a need for heat treatment system and a heat treatment method in which even an unskilled operator can easily regulate the temperature without saturating power of the heater.

### SUMMARY

The present disclosure provides, in some embodiments, a heat treatment system, a heat treatment method, and a program which enable the easy regulation of temperature.

According to a first aspect of the present disclosure, a heat treatment system is provided. The heat treatment system includes a heating unit configured to heat an inside of a processing chamber receiving a plurality of objects to be processed and a heat treatment condition storing unit configured to store a heat treatment condition in accordance with a process content, the heat treatment condition comprising a temperature inside the processing chamber heated by the heating unit. Further, the heat treatment system includes a power change model storing unit configured to store a model showing a relationship between a temperature change inside the processing chamber and a power change of the heating unit, and a changed temperature receiving unit configured to receive information on a change of the temperature inside the processing chamber, the temperature inside the processing chamber being stored in the heat treatment condition storing unit. The heat treatment system also includes a power calculation unit configured to calculate power of the heating unit required at a changed temperature inside the processing chamber based on the changed temperature received by the changed temperature receiving unit and the model stored in the power change model storing unit, and a determining unit configured to determine whether the power of the heating unit calculated by the power calculation unit is saturated.

According to a second aspect of the present disclosure, a heat treatment method is provided. The heat treatment method includes storing a heat treatment condition in accordance with a process content, the heat treatment condition comprising a temperature inside a processing chamber heated by a heating unit configured to heat an inside of the processing chamber receiving a plurality of objects to be processed, and storing a model showing a relationship between a temperature change inside the processing chamber and a power change of the heating unit. The heat treatment method further includes receiving information on a change of the temperature inside the processing chamber, the temperature inside the processing chamber being stored in storing the heat treatment condition, calculating power of the heating unit required at a changed temperature inside the processing chamber based on the changed temperature received in receiving the information on the change of the temperature inside the processing chamber and the model stored in storing the model showing the relationship, and determining whether the power of the heating unit calculated in the calculating of power is saturated.

According to a third aspect of the present disclosure, a non-transitory computer-readable recording medium is provided. The non-transitory computer-readable recording medium causes a computer to perform as a heat treatment condition storing unit configured to store a heat treatment condition in accordance with a process content, the heat treatment condition comprising a temperature inside a processing chamber heated by a heating unit configured to heat an inside of the processing chamber receiving a plurality of objects to be processed, and a power change model storing unit configured to store a model showing a relationship between a temperature change inside the processing chamber and a power change of the heating unit Further, the program is configured to cause a computer to function as a changed temperature receiving unit configured to receive information on a change of the temperature inside the processing chamber, the temperature inside the processing chamber being stored in the heat treatment condition storing unit, a power calculation unit configured to calculate power of the heating unit required at a changed temperature inside the processing chamber based on the changed temperature received by the changed temperature receiving unit and the model stored in the power change model storing unit, and a determining unit configured to determine whether the power of the heating unit calculated by the power calculation unit is saturated.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram illustrating a structure of a heat treatment apparatus according to an embodiment of the present disclosure.

FIG. 2 is a diagram illustrating a configuration example of a control unit of FIG. 1.

FIG. 3 is a diagram illustrating zones inside a reaction tube.

FIG. 4 is an example of a model showing a relationship between a temperature change and a power change of a heater.

FIG. 5 is a flowchart for describing regulating process.

FIGS. 6A to 6C are diagrams respectively showing film thicknesses, temperatures before changed, and powers of heaters at the temperature before changed, which have been input by an operator.

FIGS. 7A and 7B are diagrams respectively showing temperature changes input by the operator and respective differences “(Delta-T)” between temperatures before changed and temperatures after changed.

FIG. 8 is an example of a model showing a relationship between a temperature change of a heater and a thickness change of a formed SiO₂ film.

FIG. 9 is a diagram showing an example of a screen which displays power of a heater being saturated.

FIG. 10 is a diagram showing an example of a screen which displays the change of a temperature being proposed.

FIG. 11 is a diagram showing film thicknesses after regulation of a SiO₂ film.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

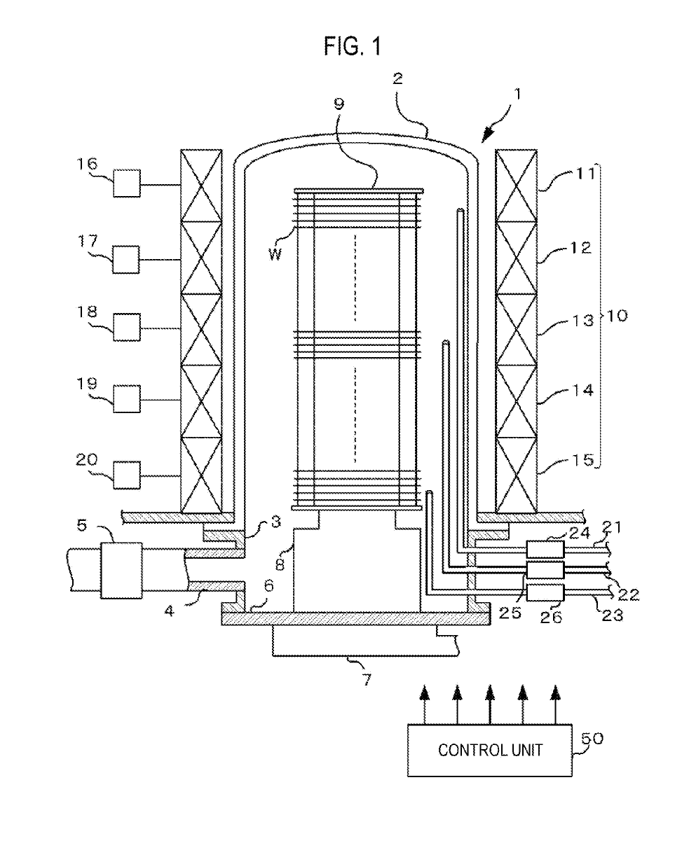

Hereinafter, an embodiment of the present disclosure will be described as an example, where a heat treatment system, heat treatment method, and program of the present disclosure are applied to a batch-type vertical heat treatment apparatus illustrated in FIG. 1. Also, in this embodiment of the present disclosure, a SiO₂ film is formed on a semiconductor wafer by using dichlorosilane (SiH₂Cl₂) and dinitrogen monoxide (N₂O) as film-forming gases.

As illustrated in FIG. 1, a heat treatment apparatus 1 according to the embodiment includes a substantially cylindrical reaction tube 2 having a ceiling. The reaction tube 2 is disposed at a longitudinal direction of the reaction tube 2 and is oriented in a vertical direction. The reaction tube 2 is made of a material (for example, quartz) having excellent thermal resistance and corrosive resistance.

A substantially cylindrical manifold 3 is disposed below the reaction tube 2. An upper end of the manifold 3 is air-tightly joined to a lower end of the reaction tube 2. An exhaust pipe 4 through which a gas in the reaction tube 2 is discharged is air-tightly connected to the manifold 3. A pressure regulating unit 5 composed of, e.g., a valve and a vacuum pump is installed to the exhaust pipe 4, thereby regulating the inside of the reaction tube 2 to a desired pressure (vacuum degree).

A lid 6 is disposed below the manifold 3 connected to reaction tube 2. The lid 6 is configured to be vertically movable by a boat elevator 7. When the lid 6 is moved upward by the boat elevator 7, a lower side which is a furnace opening portion of the manifold 3 connected to reaction tube 2 is closed, and when the lid 6 is lowered by the boat elevator 7, the lower side (furnace opening portion) of the manifold 3 connected to reaction tube 2 is opened.

A wafer boat 9 is installed through a heat-insulating tube (heat insulator) 8, on the lid 6. The wafer boat 9 is a wafer holder that receives (holds) an object to be processed, for example, a semiconductor wafers W. In the embodiment, the wafer boat 9 can receive a plurality of semiconductor wafers W (for example, 150 semiconductor wafers) with predetermined vertical intervals therebetween. Furthermore, as the boat elevator 7 moves upward the lid 6 on which the wafer boat 9 receiving semiconductor wafers W is placed, the semiconductor wafers W is loaded into the reaction tube 2.

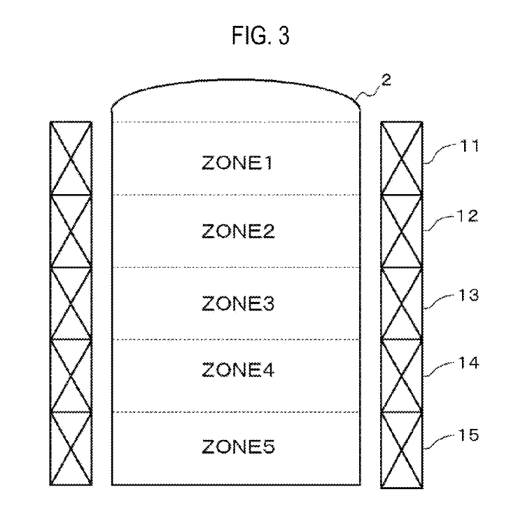

As a heating unit, a heating unit 10 formed of, e.g., a heating resistor is disposed around the reaction tube 2 to surround the reaction tube 2. The inside of the reaction tube 2 is heated to a predetermined temperature by the heating unit 10, so that the semiconductor wafers W is heated to a predetermined temperature. The heating unit 10, for example, is composed of heaters 11 to 15 that are respectively disposed on five stages, and power controllers 16 to 20 are respectively connected to the heaters 11 to 15. By independently supplying power to the power controllers 16 to 20, the heaters 11 to 15 may be independently heated to desired temperatures. As such, the inside of the reaction tube 2 is divided into five zones by the heaters 11 to 15, which are described with reference to FIG. 3. For example, when a top (ZONE 1) in the reaction tube 2 is heated, the heater 11 is heated to a desired temperature by controlling the power controller 16. When a center [CTR (ZONE 3)] of the reaction tube 2 is heated, the heater 13 is heated to a desired temperature by controlling the power controller 18. When a bottom [BTM (ZONE 5)] of the reaction tube 2 is heated, the heater 13 is heated to a desired temperature by controlling the power controller 20.

Moreover, a plurality of process-gas supply pipes for supplying a process-gas into the reaction tube 2 is disposed in the manifold 3. Also, in FIG. 1, three process-gas supply pipes 21 to 23 for supplying the process-gas into the manifold 3 are illustrated. The process-gas supply pipe 21 is provided to be extended from a side of the manifold 3 near to an upper portion of the wafer boat 9 (ZONE 1). The process-gas supply pipe 22 is provided to be extended from the side of the manifold 3 near to a center of the wafer boat 9 (ZONE 3). The process-gas supply pipe 23 is provided to be extended from the side of the manifold 3 near to a lower portion of the wafer boat 9 (ZONE 5).

Flow-rate regulating units 24 to 26 are respectively disposed in the process-gas supply pipes 21 to 23. The flow-rate regulating units 24 to 26 are respectively configured with mass flow controllers (MFC) for regulating a flow rate of process-gases in the process-gas supply pipes 21 to 23. Therefore, respective process-gases supplied from the process-gas supply pipes 21 to 23 are regulated to a desired flow rate by the flow-rate regulating units 24 to 26, and then, supplied into the reaction tube 2.

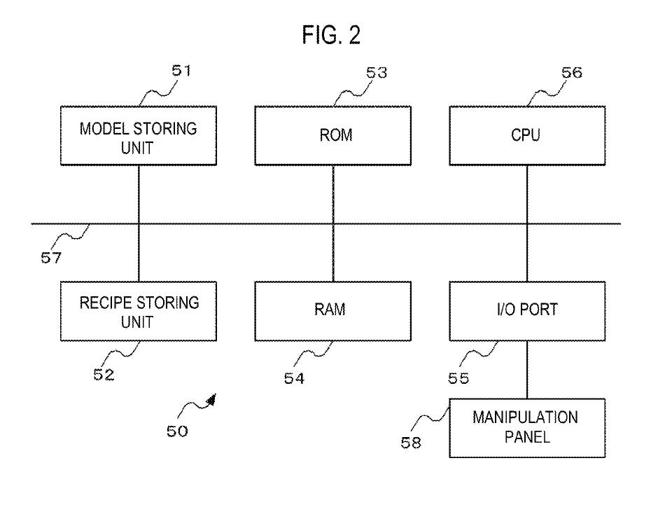

Moreover, the heat treatment apparatus 1 includes a control unit (controller) 50 for controlling processing parameters such as a gas flow rate, a pressure, a processing-atmosphere temperature inside the reaction tube 2. The control unit 50 respectively outputs control signals to the flow-rate regulating unit 24 to 26, the pressure regulating unit 5, and the power controllers 16 to 20 for the heaters 11 to 15. FIG. 2 illustrates a configuration of the control unit 50.

As illustrated in FIG. 2, the control unit 50 includes a model storing unit 51, a recipe storing unit 52, a read-only memory (ROM) 53, a random access memory (RAM) 54, an input/output (I/O) port 55, a central processing unit (CPU) 56, and a bus 57 connecting these units to each other.

The model storing unit 51 stores a model showing a relationship between a temperature change and a power change of a heater, as a power change model storing unit. Also, details of the model will be described later.

The recipe storing unit 52 stores a process recipe for determining a control sequence according to a type of a film forming process executed in the heat treatment apparatus 1, as a heat treatment condition storing unit. The process recipe is prepared for each processing (process) which a user actually performed, and defines temperature changes of respective parts, a pressure change inside the reaction tube 2, a timing for starting and stopping a gas supply, and a supply amount of a gas, from when the semiconductor wafers W are loaded into the reaction tube 2 until when the processed semiconductor wafers W are unloaded therefrom.

The ROM 53 is a recoding medium which is configured with an electrically erasable programmable read-only memory (EEPROM), a flash memory, a hard disk, or the like, and stores an operation program of the CPU 56. The RAM 54 acts as a working area of the CPU 56.

The I/O port 55 supplies measurement signals regarding a temperature, a pressure, and a flow rate of a gas to the CPU 56, and simultaneously outputs the control signals from the CPU 56 to the respective parts such as the pressure regulating unit 5, the power controllers 16 to 20 for respective heaters 11 to 15, and the flow-rate regulating units 24 to 26. Also, a manipulation panel 58 by which an operator manipulates the heat treatment apparatus 1 is connected to the I/O port 55.

The CPU 56, which configures a central element of the control unit 50, executes the operation program stored in the ROM 53, and controls an operation of the heat treatment apparatus 1 based on the process recipe stored in the recipe storing unit 52 according to an instruction from the manipulation panel 58.

Moreover, the CPU 56 calculates the power changes of the respective heaters 11 to 15 disposed in zones (ZONEs 1 to 5) inside the reaction tube 2 based on the model stored in the model storing unit 51 and the respective setting temperatures of the heaters 11 to 15. The CPU 56 calculates powers of the heaters 11 to 15 at the respective setting temperatures based on the calculated power changes of the respective heaters 11 to 15. Furthermore, the CPU 56 determines whether the powers of the heaters 11 to 15 at the respective setting temperatures are saturated (0% or 100%). The bus 57 transfers information among the respective parts.

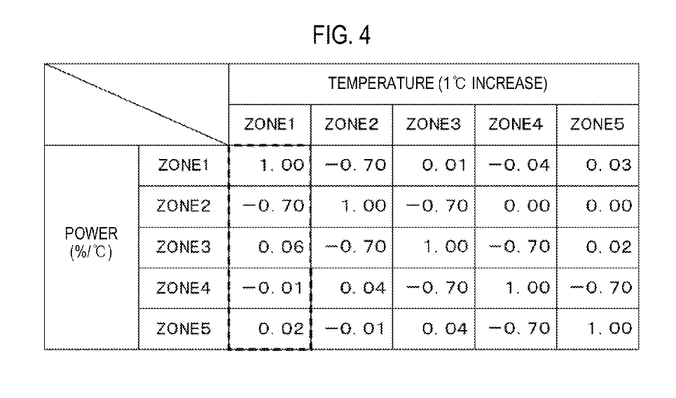

Next, the model stored in the model storing unit 51 will be described. As described above, the model storing unit 51 stores the model showing a relationship between a temperature change and a power change of a heater. Generally, when a temperature of one position (ZONE) inside the reaction tube 2 is changed, in addition to a heater power of this ZONE, heater power of the other ZONE is affected by the temperature change. FIG. 4 illustrates an example of this model.

As shown in FIG. 4, the model shows how much powers of the heaters disposed in the respective ZONEs are changed, when a temperature of each heater disposed in a specific ZONE is increased by one degree C.

For example, a portion surrounded by a broken line in FIG. 4 shows the power of the heater 11 in the ZONE 1 being increased by 1.00%, the power of the heater 12 in the ZONE 2 being decreased by 0.70%, the power of the heater 13 in the ZONE 3 being increased by 0.06%, the power of the heater 14 in the ZONE 4 being decreased by 0.01%, and the power of the heater 15 in the ZONE 5 being increased by 0.02%, when a temperature setting value of the heater 11 in the ZONE 1 is increased by one degree C. by controlling the power controller 16.

Moreover, this model is preferable to show how much power of the heaters of the respective ZONEs is changed when a temperature of a heater of a specific ZONE is changed. The other models may be used.

Moreover, considering a case in which a default value is not optimized due to a process condition or a device state, a model learning may be performed in this model by adding an extended Kalman filter or the like to software in order to provide a learning function.

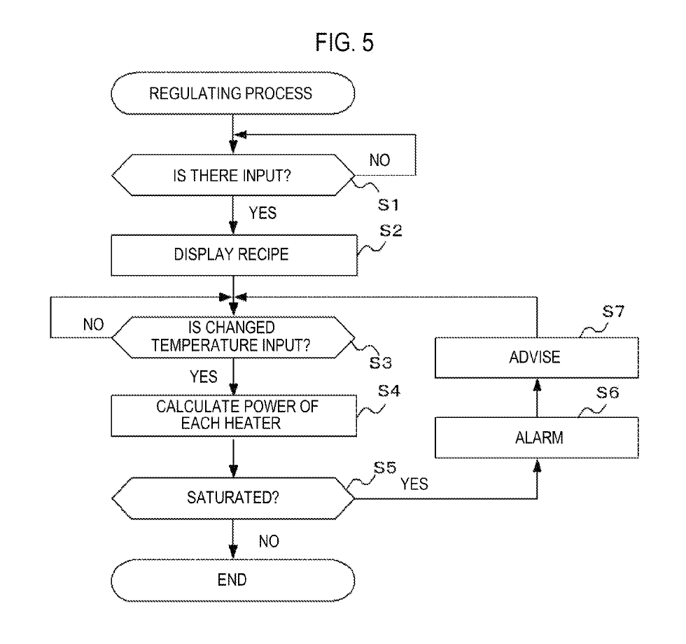

The following description will be made on a regulation method (regulating process) that regulates a temperature inside the reaction tube 2 (each of the ZONEs 1 to 5) using the heat treatment apparatus 1 having the above-described configuration. The regulating process may be performed in a setup operation before a film forming process, or the regulating process may be performed simultaneously with the film forming process. FIG. 5 is a flowchart for describing the regulating process of this example.

In the regulating process of this example, the operator manipulates the manipulation panel 58 so as to select a process type, for example, a forming process (DCS-HTO) for forming a SiO₂ film from dichlorosilane (SiH₂Cl₂) and dinitrogen monoxide (N₂O), and simultaneously to input a targeted thickness of the SiO₂ film.

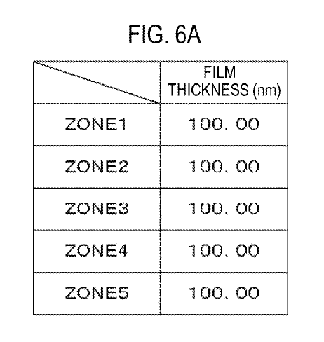

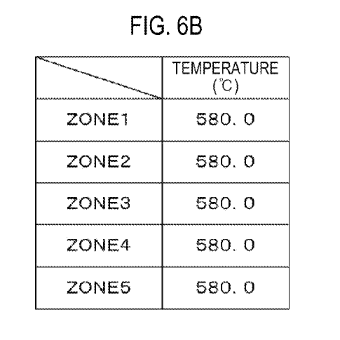

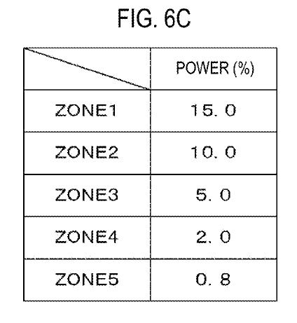

First, the control unit 50 [CPU 56] determines whether the process type or the like is input (operation S1). When it is determined that necessary information is input (operation S1; YES), the CPU 56 reads a process recipe, corresponding to the input process type from the recipe storing unit 52, and displays the process recipe on the manipulation panel 58 (operation S2). As shown in FIG. 6B, the process recipe stores temperatures of the ZONEs 1 to 5 in a selected process. Also, as shown in FIG. 6C, the CPU 56 calculates powers of the heaters 11 to 15 from the stored temperatures of the ZONEs 1 to 5. Also, if there are logs executed at the corresponding temperatures, the CPU 56 may use the values of the logs without calculating the powers of the heaters 11 to 15.

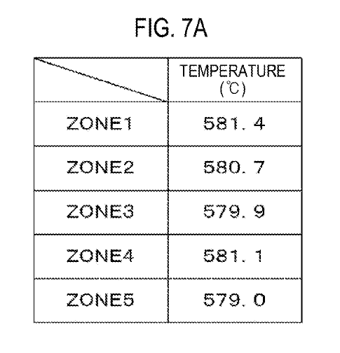

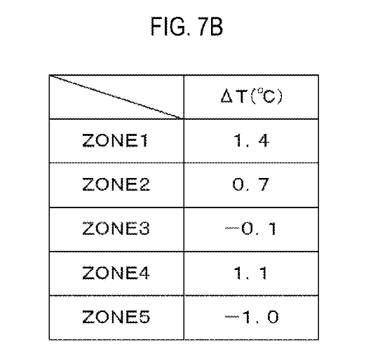

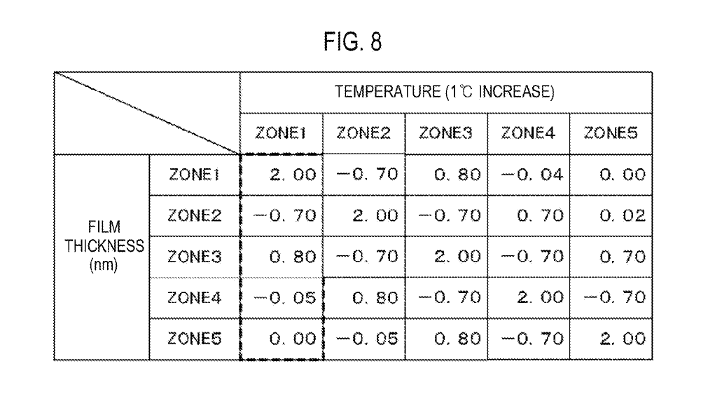

When the temperatures of the ZONEs 1 to 5 are displayed on the manipulation panel 58, the operator inputs changed temperatures of the ZONEs 1 to 5 by manipulating the manipulation panel 58, as shown in FIG. 7A. Here, for example, the changed temperatures of the ZONEs 1 to 5 may be calculated using a model of FIG. 8 that shows a relationship between a temperature change of a heater and a thickness change of a formed SiO₂ film. This model shows how much a SiO₂ film thicknesses of a semiconductor wafer W disposed in each ZONE is changed when a temperature of a heater disposed in a specific ZONE is changed. For example, as the operator manipulates the manipulation panel 58 to specify the changed amounts of the SiO₂ film thicknesses of a semiconductor wafer W disposed in each ZONE, that is, the operator uses the changed amounts of the SiO₂ film thicknesses and the model, thereby calculating changed temperatures of the ZONEs 1 to 5.

Subsequently, the CPU 56 determines whether the changed temperatures of the ZONEs 1 to 5 are input, as a changed temperature receiving unit (operation S3). When it is determined that the changed temperatures are input (operation S3; YES), the CPU 56 calculates powers of the heaters 11 to 15 at the changed temperatures, as a power calculation unit.

Power P of each of the heaters 11 to 15 at the changed temperatures, for example, may be calculated as expressed in the following Equation;

(P)=(M)×(Delta-T)+(P0)

where (M) denotes a model showing a relationship between a temperature change and a power change of a heater (shown in FIG. 4), (Delta-T) denotes a temperature difference between before and after inputting the changed temperature, and (P0) denotes power of the heater at a stored temperature in FIG. 6C. Also, the temperature difference (Delta-T) is calculated from the input changed temperature of FIG. 7A and the stored temperature of FIG. 6B.

The CPU 56 determines at least one of the powers of the heaters 11 to 15 at the temperature changes is saturated (0% or 100%), as a determining unit (operation S5). When it is determined that all of the powers of the heaters 11 to 15 are not saturated (operation S5; NO), the CPU 56 ends this operation.

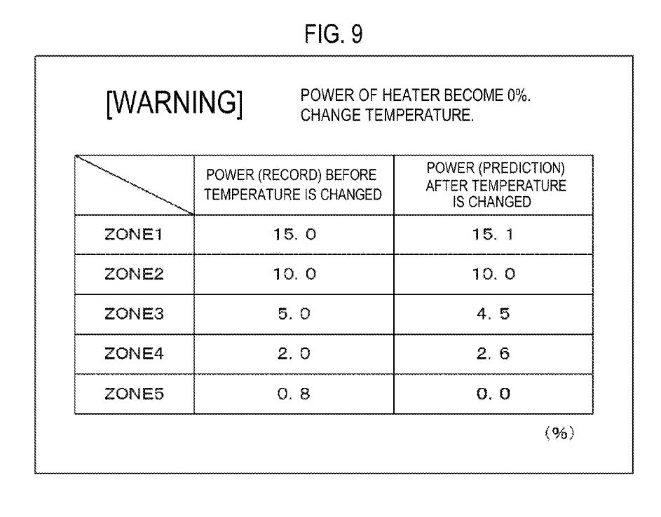

As shown in FIG. 9, when it is determined that at least one of the powers of the heaters 11 to 15 is saturated (operation S5; YES), the CPU 56 alarms the operator of a saturation information, as an alarming unit (operation S6). For example, the CPU 56 displays the saturation information shown in FIG. 9 on the manipulation panel 58.

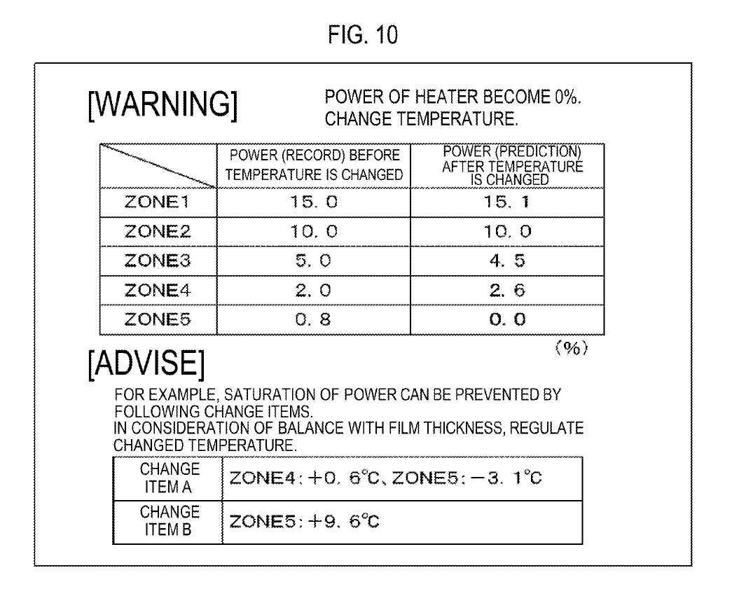

Moreover, as shown in FIG. 10, the CPU 56 advises a new temperature at which all of the powers of the heaters 11 to 15 are not saturated (operation S7). For example, the CPU 56 calculates a changed temperature at which the powers of the heaters 11 to 15 cannot be saturated. This temperature calculation is based on the thickness of the SiO₂ film of FIG. 6A and the model of FIG. 8 showing the relationship between the temperature change of the heater and the thickness change of the formed SiO₂ film. Also, the CPU 56 may calculate a plurality of changed temperatures so as to advise a plurality of changed temperatures. For example, as shown in FIG. 10, the CPU 56 displays the plurality of changed temperatures in the manipulation panel 58. Then, the regulating process returns to operation S3.

Moreover, after the regulating process ends, the CPU 56 carries out film forming process for forming a SiO₂ film on a semiconductor wafer W. Specifically, the CPU 56 allows the boat elevator 7 (lid 6) to be lowered such that the wafer boat 9, on which semiconductor wafers W are mounted in at least one of the ZONEs 1 to 5, can be disposed on the lid 6. Subsequently, the CPU 56 makes the boat elevator 7 (lid 6) to move upward such that the wafer boat 9 (semiconductor wafers W) can be loaded into the reaction tube 2. Then, the CPU 56 allows the SiO₂ film to be formed on the semiconductor wafers W by controlling the pressure regulating unit 5, the power controllers 16 to 20 for the respective heaters 11 to 15, and the flow-rate regulating unit 24 to 26, according to the recipe read from the recipe storing unit 52.

After the film forming process ends, the CPU 56 allows the boat elevator 7 (lid 6) to be lowered, the semiconductor wafers W on which the SiO₂ film formed to be unloaded out of the reaction tube 2, the semiconductor wafers W to be transferred to e.g., a measurement apparatus (not shown), and the measurement apparatus to measure the thickness of the SiO₂ film formed on the semiconductor wafers W. The measurement apparatus measures the film thickness of the SiO₂ film formed on each monitor wafer, and transfers data of the measured thickness of the SiO₂ film to the heat treatment apparatus 1 (CPU 56).

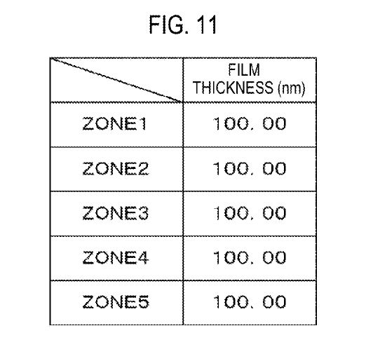

When the CPU 56 receives the measured thickness of the SiO₂ film, the CPU 56 determines whether the received film thickness data is identical to the input film thickness of the SiO₂ film. If there is a difference therebetween, the CPU 56 again performs the regulating process. However, in this example, the received film thickness data shown in FIG. 11 was identical to the input film thickness of the SiO₂ film. Accordingly, any unskilled operator on a heat treatment apparatus or a process can easily control a temperature so as to form the targeted SiO₂ film on a surface of the semiconductor wafer W.

As described above, according to the embodiment, the powers of the heaters 11 to 15 may be calculated by inputting the changed temperatures of the ZONEs 1 to 5. Accordingly, even an operator having no knowledge or experience of the heat treatment apparatus or the process can easily control a temperature so as to form the targeted SiO2 film on a surface of the semiconductor wafer W.

Moreover, according to the embodiment, when it is determined that at least one of the powers of the heaters 11 to 15 is saturated, information indicating the saturation is displayed (warned) on the manipulation panel 58, and thus, the operator can easily know that at least one of the powers of the heaters 11 to 15 is saturated.

Moreover, according to the embodiment, by advising a temperature at which all of the powers of the heaters 11 to 15 are not saturated, even an operator having no knowledge or experience of the heat treatment apparatus or the process can easily control a temperature so as to form the targeted SiO2 film on the surface of the semiconductor wafer W.

Moreover, according to the embodiment, the temperature changes of the ZONEs 1 to 5 are calculated using a relationship between a temperature change of a heater and a thickness change of a formed SiO₂ film, and thus, even an operator, having no knowledge or experience of the heat treatment apparatus or the process can easily control a temperature so as to form the targeted SiO2 film on the surface of the semiconductor wafers W.

Further, the present disclosure is not limited to the above-described embodiment, and various modifications and applications of the present disclosure are possible. Hereinafter, other embodiments applicable to the present disclosure will be described.

In the above-described embodiment, the present disclosure has been described, giving as an example the case in which the model of FIG. 8 showing a relationship between a temperature change of a heater and a thickness change of a formed SiO₂ film is used, but it is possible not to use this model. In case of not using this model, the operator inputs the changed temperatures of the ZONEs 1 to 5 as shown FIG. 7A without previously inputting a targeted thickness of SiO₂ film. Then, in operation S7, with no consideration of a film thickness, the CPU 56 only advises a temperature at which all of the powers of the heaters 11 to 15 are not saturated. Also, the operator inputs a changed temperature based on the advised temperature, for example, considering the balance of a film thickness.

In the above-described embodiment, the present disclosure has been described, giving as an example the case in which when it is determined that at least one of the powers of the heaters 11 to 15 is saturated, the operator is warned by displaying information indicating the saturation on the manipulation panel 58, and then is advised of a temperature at which all of the powers of the heaters 11 to 15 are not saturated. However, as another example, the operator can be warned by displaying only information indicating saturation in the manipulation panel 58, and not be advised of the temperature at which all of the powers of the heaters 11 to 15 are not saturated. In this case, an operator having no knowledge or experience of the heat treatment apparatus or the process can also easily control a temperature so as to form a targeted SiO2 film on the surface of the semiconductor wafers W.

In the above-described embodiment, the present disclosure has been described, giving as an example the case in which it is determined whether at least one of the powers of the heaters 11 to 15 is saturated when regulating a temperature inside the reaction tube 2 (each of the ZONEs 1 to 5). However, the powers of the heaters 11 to 15 are changed by regulating a temperature inside the reaction tube 2, and further, for example, may be changed dependent on a thickness of a accumulated film adhered to the inside of the reaction tube 2. In this case, it is preferable to make a model of a relationship between the accumulated film thickness and the powers and to continuously monitor “whether power is saturated if the film forming process is performed in the current thickness of the accumulated film” without the temperature regulation, whenever each film forming process is performed. Also, a plurality of models showing a relationship between a temperature change and a power change of a heater may be used, or a model showing a relationship among a thickness change of an accumulated film, a temperature change, and a power change of a heater may be used. Also, it may be determined whether at least one of the powers of the heaters 11 to 15 is saturated using an accumulated time of usage instead of the thickness of the accumulated film.

In the above-described embodiment, the present disclosure has been described, giving as an example the case in which the SiO₂ film is formed using dichlorosilane and dinitrogen monoxide, but a SiN film may be formed using dichlorosilane and ammonium (NH₃).

In the above-described embodiment, the present disclosure has been described, giving as an example the case in which the SiO₂ film is formed, but the type of processing is arbitrary. The present disclosure may be applied to various batch type heat treatment apparatuses such as chemical vapor deposition (CVD) apparatuses, oxidation apparatuses for forming a different kind of film.

In the above-described embodiment, the present disclosure has been described, giving as an example the case in which the number of stages of heaters (number of zones) is five, but the number of stages of heaters (number of zones) may be equal to or less than four or may be equal to or more than six. Also, the number of semiconductor wafers W extracted from each zone may be set arbitrarily.

In the above-described embodiment, the present disclosure has been described, giving as an example the case in which the batch type heat treatment apparatus having a single-pipe structure is used. However, the present disclosure may be applied to a batch type vertical heat treatment apparatus having a double-pipe structure of reaction tube 2 which is configured with an inner pipe and an outer pipe. Also, the present disclosure is not limited to processing of a semiconductor wafer, and may be applied to processing of an FPD substrate, a glass substrate, a PDP substrate, or the like.

The control unit 50 according to the embodiment of the present disclosure can be realized by a normal computer system, in addition to a dedicated system. For example, the control unit 50 which executes the above processes can be realized by, for example, installing a program for executing the above processes in a general-purpose computer from a recordable medium (flexible disk, CD-ROM, or the like) which stores the above program.

Means for providing such programs is arbitrary. The program can be provided through a predetermined recordable medium as explained above. Alternatively, the program can be provided through e.g., a communication line, a communication network, or a communication system. In this case, for example, the program may be placed on a bulletin board (BBS) of a communication network, and the program may be provided by superposing the program on a carrier wave through the network. The above process can be performed by starting the provided program and executing the same under control of an OS, similarly to other application programs.

The present disclosure is useful for a heat treatment system for heat treatment an object to be processed such as a semiconductor wafer or the like.

According to the present disclosure, a temperature can be easily regulated.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A heat treatment system, comprising:
a heating unit configured to heat an inside of a processing chamber which receives a plurality of objects to be processed;
a heat treatment condition storing unit configured to store a heat treatment condition in accordance with a process content, the heat treatment condition comprising a temperature inside the processing chamber heated by the heating unit;
a power change model storing unit configured to store a model showing a relationship between a temperature change inside the processing chamber and a power change of the heating unit;
a changed temperature receiving unit configured to receive information on a change of the temperature inside the processing chamber, the temperature inside the processing chamber being stored in the heat treatment condition storing unit;
a power calculation unit configured to calculate a power of the heating unit required at a changed temperature inside the processing chamber based on the changed temperature received by the changed temperature receiving unit and the model stored in the power change model storing unit; and
a determining unit configured to determine whether the power of the heating unit calculated by the power calculation unit is saturated.

2. The heat treatment system of claim 1, further comprising an alarming unit configured to output information on a saturated power of the heating unit, when the determining unit determines that the power of the heating unit is saturated.

3. The heat treatment system of claim 2, wherein the alarming unit calculates a temperature at which the power of the heating unit is not saturated, and notifies information on the calculated temperature.

4. The heat treatment system of claim 1, wherein,
the processing chamber is divided into a plurality of zones,
the model stored in the model storing unit shows a relationship between a temperature change in each zone of the processing chamber and a power change of a heating unit to each zone of the processing chamber,
the heating unit sets a temperature in each zone of the processing chamber,
the temperature change receiving unit specifies a changed temperature in each zone of the processing chamber, and
the power calculation unit calculates power of the heating unit to each zone of the processing chamber.

5. A heat treatment method, comprising:
storing a heat treatment condition in accordance with a process content, the heat treatment condition comprising a temperature inside a processing chamber heated by a heating unit configured to heat an inside of the processing chamber receiving a plurality of objects to be processed;
storing a model showing a relationship between a temperature change inside the processing chamber and a power change of the heating unit;
receiving information on a change of the temperature inside the processing chamber, the temperature inside the processing chamber being stored in storing the heat treatment condition;
calculating a power of the heating unit required at a changed temperature inside the processing chamber based on the changed temperature received in receiving the information on the change of the temperature inside the processing chamber and the model stored in storing of the model showing the relationship; and
determining whether the power of the heating unit calculated in the calculating of power is saturated.

6. A non-transitory computer-readable recording medium that causes a computer to perform as:
a heat treatment condition storing unit configured to store a heat treatment condition in accordance with a process content, the heat treatment condition comprising a temperature inside a processing chamber heated by a heating unit configured to heat an inside of the processing chamber receiving a plurality of objects to be processed;
a power change model storing unit configured to store a model showing a relationship between a temperature change inside the processing chamber and a power change of the heating unit;
a changed temperature receiving unit configured to receive information on a change of the temperature inside the processing chamber, the temperature inside the processing chamber being stored in the heat treatment condition storing unit;
a power calculation unit configured to calculate power of the heating unit required at a changed temperature inside the processing chamber based on the changed temperature received by the changed temperature receiving unit and the model stored in the power change model storing unit; and
a determining unit configured to determine whether the power of the heating unit calculated by the power calculation unit is saturated.
